(19) United States
(12) Patent Application Publication
(10) Pub. No.: US 2007/0188812 A1
(43) Pub. Date: Aug. 16, 2007

(54) Image processing device, image reading device and image processing method

(75) Inventors: Mieko Ohkawa, Tokyo (JP); Daijiro Saito, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KONIKA MINOLTA BUSINESS TECHNOLOGIES, INC.

(21) Appl. No.: 11/446,960

(22) Filed: Jun. 6, 2006

(30) Foreign Application Priority Data
Feb. 10, 2006 (JP) 2006-033620

(51) Int. Cl. G03F 3/08

(52) U.S. Cl. 358/3.03; 358/521

(57) ABSTRACT

Disclosed herein is an image processing device, including: a gradation converter which converts a gradation value of a target pixel in multilevel image data so that the number of gradations decreases; a resolution which converts creating high-resolution image data having a resolution higher than the multilevel image data by outputting a pixel block capable of reproducing a gradation value which is same as the gradation value obtained by the gradation converter, the pixel block including a predetermined number of pixels; and an error diffusion section which executes a processing for diffusing an error value between the gradation values before a gradation conversion and after the gradation conversion by the gradation converter to peripheral pixels of the target pixel.

### CROSS-REFERENCE TO RELATED APPLICATION

The present U.S. patent application claims the priority of Japanese Patent Application No. 2006-033620 filed on Feb. 10, 2006, according to the Paris Convention, and the above Japanese Patent Application is the basis for correcting mistranslation of the present U.S. patent application.

### BACKGROUND OF THE INVENTION

1. Field of the Invention

The present invention relates to an image processing device for converting low-resolution image data into high-resolution image data, an image reading device having the image processing device and an image processing method.

2. Description of Related Art

Conventionally, there is proposed a technology for converting low-resolution image data into high-resolution image data using a pixel block composed of a predetermined number of pixels. For example, Japanese Patent Application Publication Unexamined No. 2002-271624 discloses a technology of correcting created high-resolution multilevel data for each pixel by using error data caused by quantization and quantizing the corrected high-resolution multilevel data for each pixel.

Further, Japanese Patent Application Publication Unexamined No. 2000-332995 discloses a technology of collectively performing resolution conversion using a threshold matrix (matrix in which a plurality of thresholds are sorted in the order of values and arranged in each element) corresponding to positions of a target pixel and peripheral pixels thereof. In Japanese Patent Application Publication Unexamined No. 2000-332995, a fixed pattern corresponding to positions of a target pixel and peripheral pixels thereof is used for a pixel block to be outputted.

However, the technology described in Japanese Patent Application Publication Unexamined No. 2002-271624 has a problem that since the created high-resolution image data is subjected to the correction and quantization, a memory capacity required for a processing is large and therefore, the processing is complicated. Further, the technology described in Japanese Patent Application Publication Unexamined No. 2000-332995 has a problem that since resolution conversion is collectively performed using a threshold matrix corresponding to positions of a target pixel and peripheral pixels thereof as well as the above-described fixed pattern is used for a pattern of a pixel block to be outputted, a memory capacity required for a processing is large and therefore, the processing is complicated.

### SUMMARY

An object of the present invention is to enable high-quality and high-resolution image data to be created by a simple processing.

In order to accomplish the above-described object, in accordance with an embodiment according to a first aspect of the present invention, an image processing device comprises:

a gradation converter which converts a gradation value of a target pixel in multilevel image data so that the number of gradations decreases;

a resolution converter which creates high-resolution image data having a resolution higher than the multilevel image data by outputting a pixel block capable of reproducing a gradation value which is same as the gradation value obtained by the gradation converter, the pixel block including a predetermined number of pixels; and

an error diffusion section which executes a processing for diffusing an error value between the gradation values before a gradation conversion and after the gradation conversion by the gradation converter to peripheral pixels of the target pixel.

Preferably, the gradation converter converts the gradation value of the target pixel by comparing with a plurality of predetermined thresholds.

Preferably, the plurality of predetermined thresholds can be selected by an operation of an operating section.

Preferably, the resolution converter randomly selects a pixel output order pattern from among a plurality of different pixel output order patterns for determining an output order of each pixel of the pixel block and creates the high-resolution image data in accordance with the selected pixel output order pattern.

Preferably, the resolution converter selects a pixel output order pattern in a previously specified order from among a plurality of different pixel output order patterns for determining an output order of each pixel of the pixel block and creates the high-resolution image data in accordance with the selected pixel output order pattern.

The processing executed by the error diffusion section is preferably determined by a diffusion coefficient pattern for indicating a diffusion coefficient in the peripheral pixels of the target pixel; and the diffusion coefficient pattern used in the error diffusion section can preferably be selected by an operation of an operating section from among a plurality of previously prepared diffusion coefficient patterns.

Preferably, each of the pixels within the pixel block is a binary pixel.

In accordance with an embodiment according to a second aspect of the present invention, an image reading device comprises:

an image reader which reads a document to create multilevel image data; and

the above-described image processing device.

### BRIEF DESCRIPTION OF THE DRAWINGS

The present invention will become more fully understood from the detailed description given hereinafter and the accompanying drawings given by way of illustration only, and thus are not intended as a definition of the limits of the present invention, and wherein:

FIG. 1 is a block diagram showing an essential structure of an image forming device according to an embodiment of the present invention;

FIG. 2 is a view showing an output example in the case of creating high-resolution binary image data from low-resolution multilevel image data using a pixel block;

FIGS. 3A and 3B are views showing a relationship between low-resolution image data and high-resolution image data;

FIG. 4 is a view showing a gradation value of a pixel block;

FIG. 5 is a view showing a pixel output order pattern for determining an output order of each pixel of a pixel block;

FIG. 6 is a view showing an output example in the case of creating high-resolution binary image data from low-resolution multilevel image data using a pixel block;

FIG. 7 is a view showing a diffusion coefficient pattern used in an error diffusion processing;

FIG. 8 is a view showing an output example in the case of creating high-resolution multilevel image data from low-resolution multilevel image data using a pixel block; and

FIG. 9 is a flowchart showing an image processing executed by an image processing device.

### DETAILED DESCRIPTION OF THE PREFERRED EMBODIMENTS

Preferred embodiments of the present invention will be described below by referring to drawings.

First of all, a configuration in the present embodiment will be described.

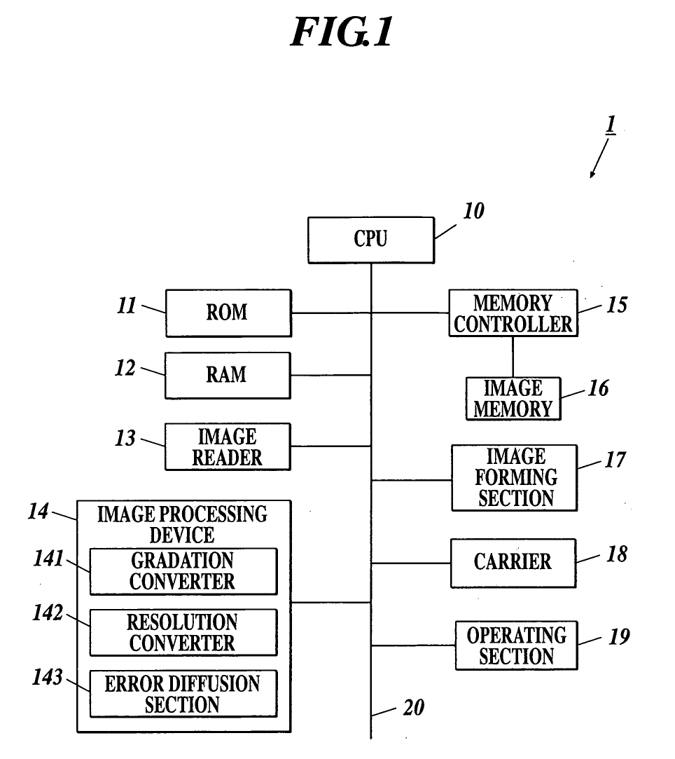

FIG. 1 shows a configuration of an image forming device 1 according to the present embodiment. As shown in FIG. 1, the image forming device 1 comprises a CPU (Central Processing Unit) 10, a ROM (Read Only Memory) 11, a RAM (Random Access Memory) 12, an image reader 13, an image processing device 14, a memory controller 15, an image memory 16, an image forming section 17, a carrier 18 and an operating section 19, in which the respective sections are connected to each other through a bus 20.

The CPU 10 controls operations of the respective sections of the image forming device 1 in accordance with control programs stored in the ROM 11.

The ROM 11 stores the control programs for realizing various functions relating to operations of the image forming device 1, which are executed by the CPU 10, and data used in the execution of the control programs. For example, the ROM 11 stores threshold or gradation conversion LUT (Look Up Table) data used in a gradation conversion processing, pixel output order pattern data (see FIG. 5) used in a resolution conversion processing, and diffusion coefficient pattern data (see FIG. 7) used in an error diffusion processing in the image processing device 14.

The RAM 12 expands various control programs executed by the CPU 10 into a program storing area and temporarily stores inputted data or data on the processing results produced during execution of the various control programs in a work area.

The image reader 13 includes a scanner and reads image information in a document by a scanner to create image data. Specifically, the image reader 13 scans a document placed on a transparent contact glass by lighting from a light source, forms an image of the reflected light on a CCD (Charge Coupled Device) and subjects the image to photoelectric conversion by the CCD, thereby creating multilevel image data and outputting the image data to the image processing device 14.

The image processing device 14 subjects the inputted multilevel image data to various image processings such as a magnification processing, a filter processing and a gamma conversion processing. In addition, the image processing device 14 has a gradation converter 141, a resolution converter 142 and an error diffusion section 143, which execute on image data to be processed a gradation conversion for performing gradation conversion by comparison with a threshold, a resolution conversion for converting the image data into high-resolution image data and an error diffusion processing, respectively. Details of processings in the gradation converter 141, the resolution converter 142 and the error diffusion section 143 will be described below.

The gradation converter 141 converts a gradation value of a target pixel in the multilevel image data inputted from the image reader 13 so that the number of gradations decreases. Specifically, the gradation converter 141 reads threshold data stored in the ROM 11 to hold the data in a threshold register (not shown) within the image processing device 14 and converts the gradation value of the target pixel by comparing with the thresholds held in the threshold register. The thresholds used in the gradation conversion may be selected by an operation of the operating section 19 by a user. Further, instead of using the thresholds, a gradation conversion LUT stored in the ROM 11 may be used in the conversion.

The resolution converter 142 outputs a pixel block capable of reproducing a gradation value which is the same as the gradation value obtained by the gradation conversion in the gradation converter 141 to create image data having a resolution higher than the inputted image data. It can be selected by an operation of the operating section 19 whether to create high-resolution image data. When creation of the high-resolution image data is selected, the processing by the resolution converter 142 may be performed.

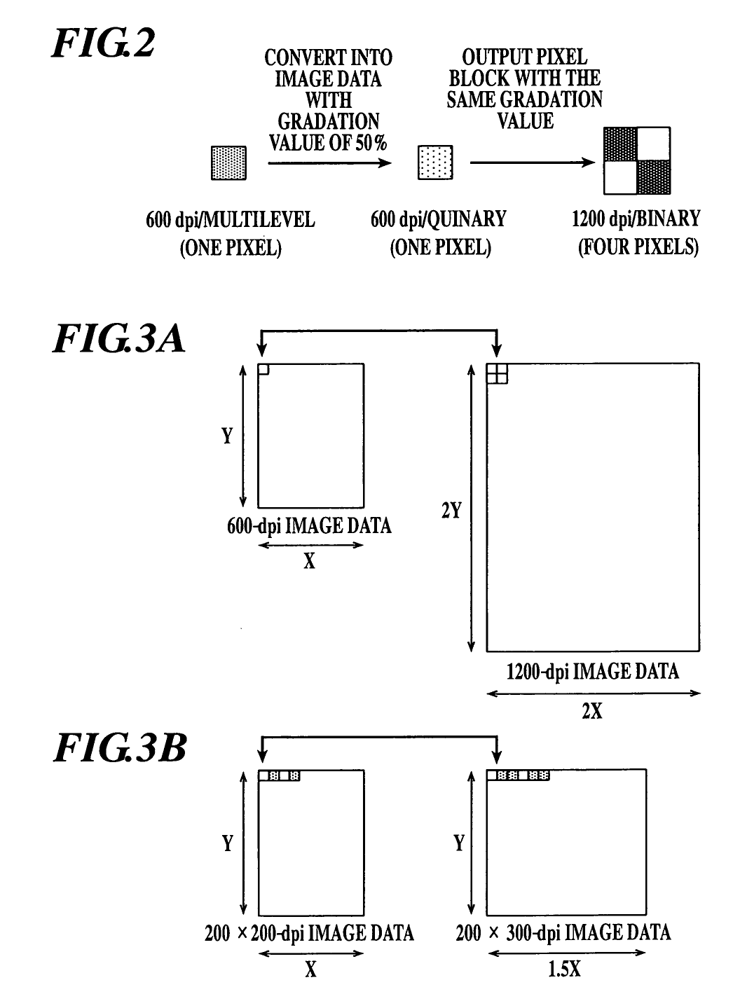

FIG. 2 shows an example of a gradation conversion by the gradation converter 141 and a resolution conversion by the resolution converter 142. In FIG. 2, a target pixel in inputted 600-dpi multilevel image data is converted into the pixel having a gradation value of 50% to serve as a 600-dpi quinary pixel and thereby, binary image data (1200 dpi) of a four-pixel block which reproduces the gradation value which is the same as that of this pixel is created.

Thus, one pixel in inputted original image data is converted by a pixel block including n×m pixels (n and m are integers of 1 or more) and thereby, high-resolution image data is created. The pixel block is determined based on sizes of original image data to be inputted and high-resolution image data to be created. For example, in the case of creating 1200-dpi image data from 600-dpi image data, one pixel in the 600-dpi image data is converted into the four-pixel block having 2 (vertical size)×2 (horizontal size) pixels and thereby, 1200-dpi image data can be created as shown in FIG. 3A.

Further, in the case of being incapable of conversion into an integral multiple pixel block, such as conversion from 200×200-dpi image data to 200×300-dpi image data, one pixel in the 200×200-dpi image data is alternately converted by one-pixel block having 1 (vertical size)×1 (horizontal size) pixel and two-pixel block having 1 (vertical size)×2 (horizontal size) pixels, whereby the 200×300-dpi image data can be created as shown in FIG. 3B.

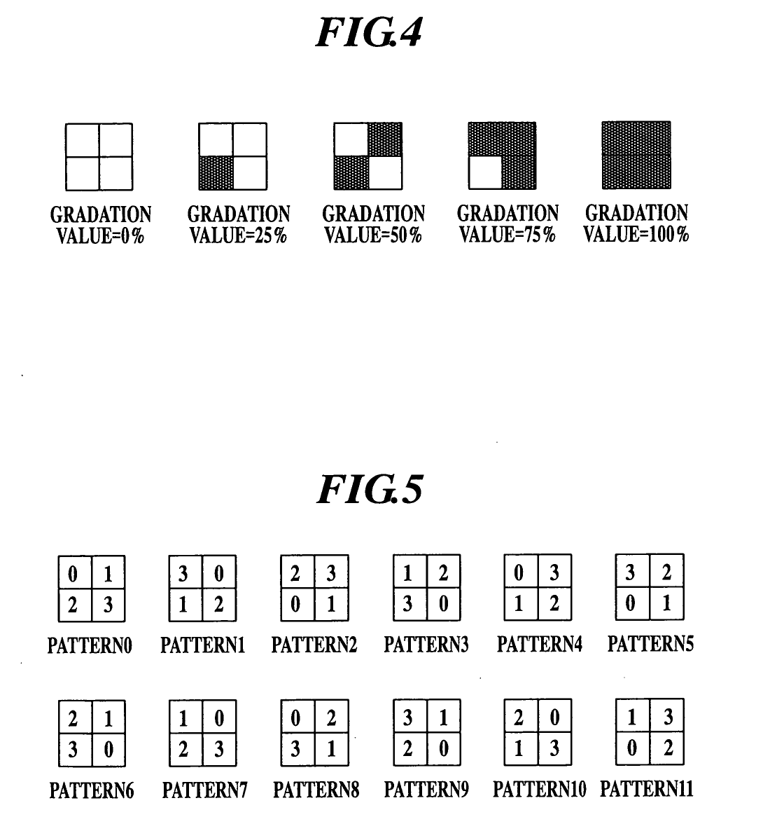

The number of gradations of a gradation value (hereinafter, referred to as an output gradation value) outputted by gradation conversion by comparison with a predetermined threshold is determined by the number of gradations of high-resolution image data to be created and by the number of pixels (hereinafter, referred to as the number of pixels in a block) n×m which form a pixel block. For example, in a case of creating 1200-dpi binary image data from 600-dpi multilevel image data, a pixel block formed from a target pixel is a four-pixel block having 2 (vertical size)×2 (horizontal size) pixels as well as the gradation values capable of reproduction by this four-pixel block are five values (0%, 25%, 50%, 75%, 100%) as shown in FIG. 4 and therefore, five outputs are provided in the gradation conversion of the target pixel by comparison with the threshold. Accordingly, the number of gradations of the output gradation value is calculated as in formula (1).

The number of gradations of output gradation value={(The number of gradations of high-resolution image data−1)×The number of pixels in a block}+1 . . . (1) In FIG. 4, the number of gradations of high-resolution image data is 2 and the number of pixels in a block is 4. Therefore, from formula (1), the number of gradations of the output gradation value is 5.

In outputting each pixel of a pixel block, the output is performed in accordance with a pixel output order pattern for determining the output order of each of the pixels forming the pixel block. In the ROM 11, data for a plurality of the different pixel output order patterns as shown in FIG. 5 (patterns 0 to 11) is stored. In FIG. 5, figures given in the respective pixels of the respective pixel output order patterns express the output order of the pixels, and the output is performed starting from a black pixel in the order of these figures.

From among the plurality of pixel output order patterns stored in the ROM 11, the resolution converter 142 randomly selects a pixel output order pattern based on random numbers generated by a random number generator (not shown), holds the selected pattern in an output order register (not shown) within the image processing device 14 and outputs the respective pixels in the output order expressed in the held pattern. Further, the pixel output order pattern may be selected in the order previously specified by an operation of the operating section 19 by a user.

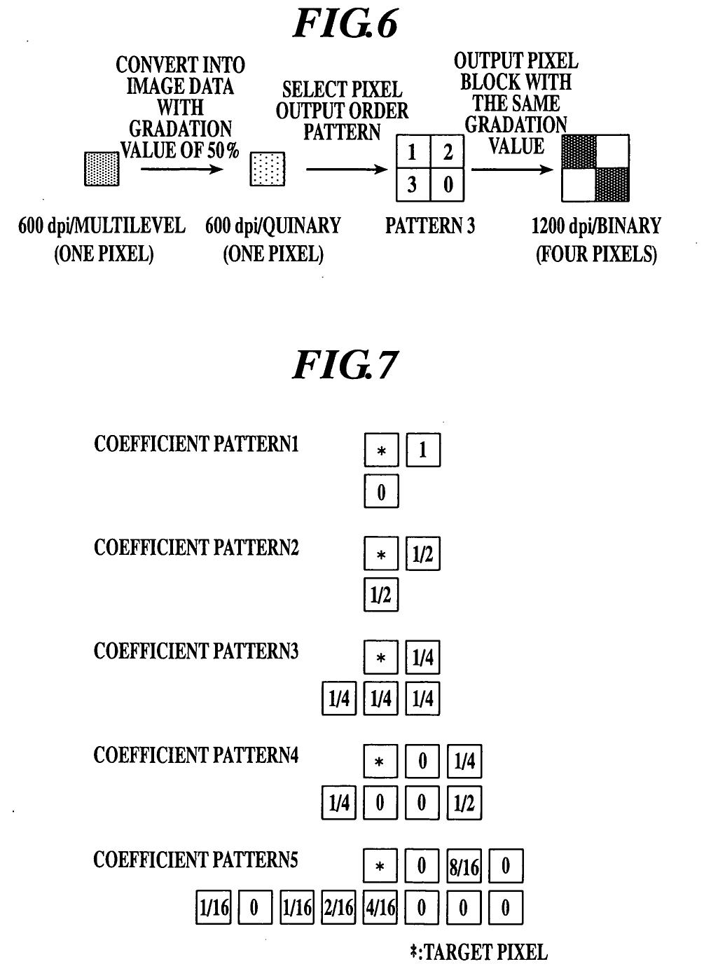

FIG. 6 shows an output example in a case where a pattern 3 is selected from among the plurality of pixel output order patterns shown in FIG. 5. As shown in FIG. 6, in order to reproduce a gradation value of 50% in a binary four-pixel block, two pixels of a four-pixel block become black pixels. On this occasion, the two pixels become black pixels in ascending order of figures given in the pattern 3. Therefore, the black pixels are outputted in the order of the lower right and upper left pixels and after the output of the block pixels, white pixels are outputted in the order of the upper right and lower left pixels.

The error diffusion section 143 holds an error value between the gradation values of the target pixel before and after the gradation conversion by the gradation converter 141 in a buffer memory (not shown) within the image processing device 14 and executes the error diffusion processing for diffusing the error value to unprocessed peripheral pixels and for adding the error value to the gradation value of each of the peripheral pixels. A diffusion method of the error value is determined based on diffusion coefficients in peripheral pixels of the target pixel. FIG. 7 shows an example (coefficient patterns 1 to 5) of the diffusion coefficient patterns. In the ROM 11, data for a plurality of the different diffusion coefficient patterns as shown in FIG. 7 is stored. The error diffusion section 143 holds a diffusion coefficient pattern previously selected by the operation of the operating section 19 by a user, in a coefficient pattern register (not shown) within the image processing device 14. Then, the section 143 multiplies the error value held in the buffer memory by each of the coefficients indicated in the diffusion coefficient pattern held in the coefficient pattern register to obtain a multiplication value and adds the multiplication value to the original gradation value of each of the peripheral pixels.

The respective processings in the gradation converter 141, the resolution converter 142 and the error diffusion section 143 are executable regardless of the number of gradations (binary, multilevel) of the high-resolution image data to be created. FIG. 8 shows an output example in a case where the high-resolution image data to be created is multilevel data. In FIG. 8, there is shown an example where when a target pixel in inputted 600-dpi multilevel image data is converted into the pixel having a gradation value of 70% and a pattern 3 in FIG. 5 is selected as a pixel output order pattern, multilevel image data (1200 dpi) of a four-pixel block which reproduces a gradation value of 70% is created. In order to reproduce a gradation value of 70% in the four-pixel block of FIG. 8, black pixels are outputted in zeroth and first pixels (lower right and upper left pixels) to reproduce a gradation value of 50%, a remaining gradation value of 20% is outputted in a second pixel (upper right pixel) and a white pixel is outputted in a third pixel.

Returning now to FIG. 1, the memory controller 15 controls access to the image memory 16 in reading and writing of the image data. The image memory 16 includes involatile storage media, and stores image data processed in the image processing device 14.

In accordance with a print control signal from the CPU 10, the image forming section 17 forms an image on a transfer paper by a predetermined printing method (e.g., an electrophotographic method or an ink-jet method). Using a plurality of rollers, the carrier 18 carries transfer papers before and after the image forming.

The operating section 19 includes various function keys such as a numeric key and a start key, and a touch panel formed integrally with a display screen such as an LCD (Liquid Crystal Display). The operating section 19 outputs an operation signal corresponding to a key operation or an operation signal corresponding to an input operation in the touch panel, to the CPU 10.

Next, operations in the present embodiment will be described.

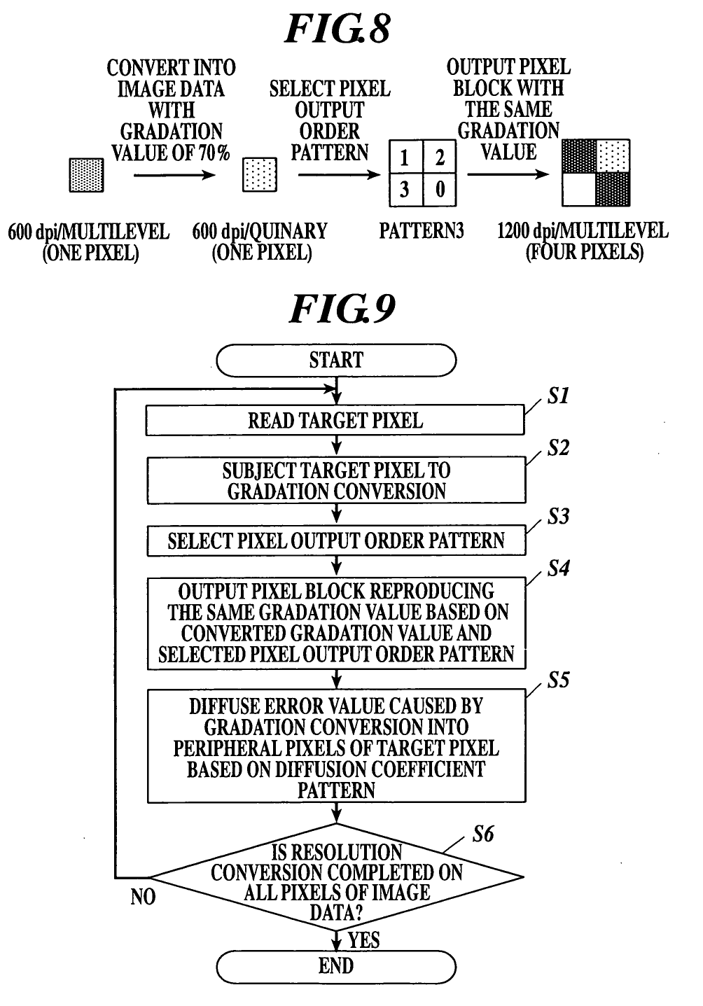

An image processing executed in the image processing device 14 will be described with reference to the flowchart in FIG. 9.

First, a target pixel to be processed is read from among image data inputted to the image processing device 14 (step S1). In the gradation converter 141, the target pixel is subjected to gradation conversion (step S2). Next, from among a plurality of the different pixel output order patterns (see FIG. 5) stored in the ROM 11, a pixel output order pattern is selected randomly or in the previously specified order (step S3).

Next, based on a gradation value of the target pixel obtained by the gradation conversion in step S2 and the pixel output order pattern selected in step S3, there is performed resolution conversion for outputting a pixel block which reproduces the same gradation value as the obtained gradation value (step S4). Next, based on a diffusion coefficient pattern previously selected, there is performed an error diffusion processing for diffusing an error value between the gradation values of the target pixel before and after the gradation conversion in step S2 to peripheral pixels of the target pixel (step S5).

Next, it is determined whether or not the resolution conversion in step S4 is completed on all the pixels of image data to be processed (step S6). In step S6, when it is determined that the processing on all the pixels is not completed (step S6; NO), the flow returns to step S1. Then, the processings in steps S1 to S5 are repeated on the target pixel to be processed. In step S6, when it is determined that the processing on all the pixels is completed (step S6; YES); this image processing is completed.

As described above, according to the image forming device 1 of the present embodiment, high-resolution image data which preserves a gradation or image quality can be created from original image data by a simple processing.

Further, in a case of performing a gradation conversion by comparison with a threshold, a threshold used in the gradation conversion can be selected, so that an image quality to be outputted can be finely adjusted.

Further, from among a plurality of pixel output order patterns, a pixel output order pattern is randomly selected, so that a texture can be prevented.

Further, from among a plurality of pixel output order patterns, a pixel output order pattern is selected in the previously specified order, so that it becomes possible to meet the needs of finely controlling an output order of each pixel.

Further, from among a plurality of diffusion coefficient patterns, a diffusion coefficient pattern used in error diffusion can be selected, so that an error diffusion method can be finely controlled as well as a degree of freedom in the error diffusion method can be enhanced.

What is claimed is:

1. An image processing device, comprising:
a gradation which converts a gradation value of a target pixel in multilevel image data so that the number of gradations decreases;
a resolution converter which creates high-resolution image data having a resolution higher than the multilevel image data by outputting a pixel block capable of reproducing a gradation value which is same as the gradation value obtained by the gradation converter, the pixel block including a predetermined number of pixels; and
an error diffusion section which executes a processing for diffusing an error value between the gradation values before a gradation conversion and after the gradation conversion by the gradation converter to peripheral pixels of the target pixel.

2. The image processing device of claim 1, wherein the gradation converter converts the gradation value of the target pixel by comparing with a plurality of predetermined thresholds.

3. The image processing device of claim 2, wherein the plurality of predetermined thresholds are selected by an operation of an operating section.

4. The image processing device of claim 1, wherein the resolution converter randomly selects a pixel output order pattern from among a plurality of different pixel output order patterns for determining an output order of each pixel of the pixel block and creates the high-resolution image data in accordance with the selected pixel output order pattern.

5. The image processing device of claim 1, wherein the resolution converter selects a pixel output order pattern in a previously specified order from among a plurality of different pixel output order patterns for determining an output order of each pixel of the pixel block and creates the high-resolution image data in accordance with the selected pixel output order pattern.

6. The image processing device of claim 1, wherein
the processing executed by the error diffusion section is determined by a diffusion coefficient pattern for indicating a diffusion coefficient in the peripheral pixels of the target pixel; and
the diffusion coefficient pattern used in the error diffusion section can be selected by an operation of an operating section from among a plurality of previously prepared diffusion coefficient patterns.

7. The image processing device of claim 1, wherein each of the pixels within the pixel block is a binary pixel.

8. An image reading device, comprising:
an image reader for reading a document to create multilevel image data; and
the image processing device of claim 1.

9. An image processing method, comprising:
converting a gradation value of a target pixel in multilevel image data so that the number of gradations decreases;
creating high-resolution image data having a resolution higher than the multilevel image data by outputting a pixel block capable of reproducing a gradation value which is same as the gradation value obtained in the converting, the pixel block including a predetermined number of pixels; and
executing a processing for diffusing an error value between the gradation values before a gradation conversion and after the gradation conversion in the converting to peripheral pixels of the target pixel.

10. The image processing method of claim 9, wherein in the converting, the gradation value of the target pixel is converted by comparing with a plurality of predetermined thresholds.

11. The image processing method of claim 10, wherein the plurality of predetermined thresholds are selected by an operation of an operating section.

12. The image processing method of claim 9, wherein in the converting, a pixel output order pattern is randomly selected from among a plurality of different pixel output order patterns for determining an output order of each pixel of the pixel block and the high-resolution image data is created in accordance with the selected pixel output order pattern.

13. The image processing method of claim 9, wherein in the converting, a pixel output order pattern is selected in a previously specified order from among a plurality of different pixel output order patterns for determining an output order of each pixel of the pixel block and the high-resolution image data is created in accordance with the selected pixel output order pattern.

14. The image processing method of claim 9, wherein
the processing for diffusing the error value is determined by a diffusion coefficient pattern for indicating a diffusion coefficient in the peripheral pixels of the target pixel; and
the diffusion coefficient pattern used in the executing of the processing can be selected by an operation of an operating section from among a plurality of previously prepared diffusion coefficient patterns.

15. The image processing method of claim 9, wherein each of the pixels within the pixel block is a binary pixel.
